(19) United States
(12) Patent Application Publication
(10) Pub. No.: US 2025/0301852 A1
(43) Pub. Date: Sep. 25, 2025

(54) LIGHT EMITTING ELEMENT AND METHOD FOR PRODUCING LIGHT EMITTING ELEMENT

(71) Applicant: Sharp Display Technology Corporation, Kameyama City, Mie (JP)

(72) Inventor: YOSHIHIRO UETA, Sakai City, Osaka (JP)

(21) Appl. No.: 18/860,918

(22) PCT Filed: Jun. 27, 2022
(86) PCT No.: PCT/JP2022/025541

§ 371 Date: Oct. 28, 2024

(51) Int. Cl. H10K 50/115; H10K 50/15; H10K 50/16

(52) U.S. Cl. CPC H10K 50/115; H10K 50/15; H10K 50/16

(57) ABSTRACT

A light-emitting element includes: a charge function layer; a light-emitting layer including a continuous film of an inorganic compound and a plurality of first quantum dots included in the continuous film; and a buffer layer including a plurality of second quantum dots in contact with the charge function layer and the continuous film.

### TECHNICAL FIELD

The disclosure relates to a light-emitting element and a manufacturing method for the light-emitting element.

### BACKGROUND ART

PTL 1 discloses a configuration including an emissive quantum dot and a non-emissive quantum dot.

### CITATION LIST

### Patent Literature

PTL 1: US 2019/0280232 A

### SUMMARY

### Technical Problem

In a light-emitting element including a plurality of quantum dots included in a continuous film of an inorganic compound, there is a problem that luminous efficiency of the light-emitting element is low.

### Solution to Problem

A light-emitting element according to an aspect of the disclosure includes a charge function layer, a light-emitting layer including a continuous film of an inorganic compound and a plurality of first quantum dots included in the continuous film, and a buffer layer including a plurality of second quantum dots in contact with the charge function layer and the continuous film.

### Advantageous Effects of Disclosure

According to an aspect of the disclosure, it is possible to increase luminous efficiency in a light-emitting element including a plurality of quantum dots included in a continuous film of an inorganic compound.

### BRIEF DESCRIPTION OF DRAWINGS

FIG. 1 is a cross-sectional view illustrating a schematic configuration of a light-emitting element according to a first embodiment of the disclosure.

FIG. 2 is an equivalent circuit diagram of the light-emitting element illustrated in FIG. 1.

FIG. 3 is a graph illustrating voltage-current characteristics of the light-emitting element illustrated in FIG. 1 and a comparative element, respectively.

FIG. 4 is a graph illustrating current density-EQE characteristics of the light-emitting element illustrated in FIG. 1 and the comparative element, respectively.

FIG. 5 is a graph illustrating voltage-EQE characteristics of the light-emitting element illustrated in FIG. 1 and the comparative element, respectively.

FIG. 6 is an enlarged view of an example of a first quantum dot and a second quantum dot, respectively.

FIG. 7 is a diagram for describing a manufacturing method for the light-emitting element illustrated in FIG. 1.

FIG. 8 is a cross-sectional view illustrating a schematic configuration of a light-emitting element according to a second embodiment of the disclosure.

FIG. 9 is a cross-sectional view illustrating a schematic configuration of a light-emitting element according to a third embodiment of the disclosure.

FIG. 10 is a diagram illustrating a band tilt of the first quantum dot and distributions of electrons and holes when an external electrical field is applied to each of the light-emitting element illustrated in FIG. 1 and the light-emitting element illustrated in FIG. 9.

FIG. 11 is a cross-sectional view illustrating a schematic configuration of a light-emitting element according to a fourth embodiment of the disclosure.

### DESCRIPTION OF EMBODIMENTS

Embodiments of the disclosure will be described below. For convenience of description, members having the same functions as the members described earlier may be denoted by the same reference signs, and the description thereof will not be repeated.

### First Embodiment

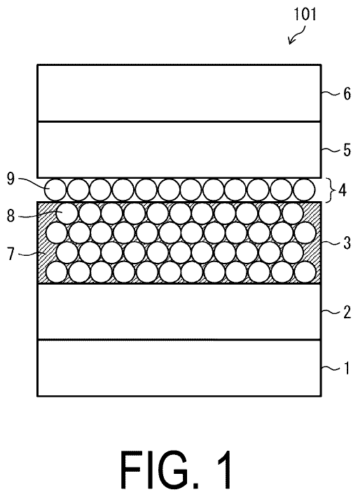

FIG. 1 is a cross-sectional view illustrating a schematic configuration of a light-emitting element 101 according to a first embodiment of the disclosure. The light-emitting element 101 includes an electrode 1, a charge function layer 2, a light-emitting layer 3, a buffer layer 4, a charge function layer 5, and an electrode 6. The light-emitting element 101 emits light by a current flowing between the electrode 1 and the electrode 6.

The charge function layer 2 includes one of (1) at least one of a hole injection layer and a hole transport layer and (2) at least one of an electron injection layer and an electron transport layer. The charge function layer 5 includes the other of (1) and (2).

The light-emitting layer 3 includes a continuous film 7 of an inorganic compound and a plurality of first quantum dots 8 included in the continuous film 7. In other words, the continuous film 7 may be formed so as to fill a space formed between the plurality of first quantum dots 8. The continuous film 7 may be a so-called base material (matrix material). The inorganic compound may be a metal sulfide. The term “continuous film” means a state having an area equal to or larger than 1000 nm² made of the inorganic compound in a plane direction orthogonal to a thickness direction of the light-emitting layer 3.

The buffer layer 4 includes a plurality of second quantum dots 9. The plurality of second quantum dots 9 are in contact with the charge function layer 5 and the continuous film 7. In the light-emitting layer 3, both the continuous film 7 and the plurality of first quantum dots 8 are not in contact with the charge function layer 5.

Junction between the buffer layer 4 and the charge function layer 5 includes special semiconductor junction. The special semiconductor junction is electrical junction between a semiconductor at the outermost periphery of each of the plurality of second quantum dots 9 and the semiconductor configuring the charge function layer 5. On the other hand, between the light-emitting layer 3 and the charge function layer 5, there is no semiconductor junction other than the special semiconductor junction, or an area of the semiconductor junction other than the special semiconductor junction is negligibly small as compared with an area of the special semiconductor junction. Charges are injected from the charge function layer 5 into each of the plurality of first quantum dots 8 substantially only through the special semiconductor junction.

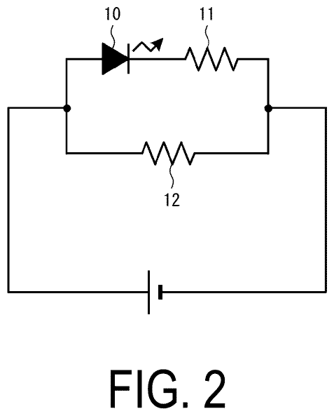

FIG. 2 is an equivalent circuit diagram of the light-emitting element 101. The light-emitting element 101 can be represented by a parallel circuit of a quantum dot light-emitting diode (QLED) 10 and a resistor 11 connected in series to the QLED 10, and a shunt resistor 12.

The resistor 11 corresponds to a resistance component of the light-emitting element 101 including wiring, and is generally around an order of several tens to several hundreds of ohms. The shunt resistor 12 corresponds to insulation properties (degree of leakage current) of the light-emitting element 101. A resistance value of the shunt resistor 12 is usually on an order of several megaohms to several tens of megaohms, and a current flowing through the shunt resistor 12 is practically negligible.

In the light-emitting element 101, when an external electrical field is applied, the charges are injected into each of the plurality of first quantum dots 8 through the special semiconductor junction, and the charges moving through the semiconductor junction other than the special semiconductor junction are negligible as described above. Voltage-current characteristics at this point are substantially the same as that of a single light-emitting diode. Radiative recombination occurs in almost all the charges injected into each of the plurality of first quantum dots 8. Accordingly, it is possible to achieve the light-emitting element 101 having high luminous efficiency.

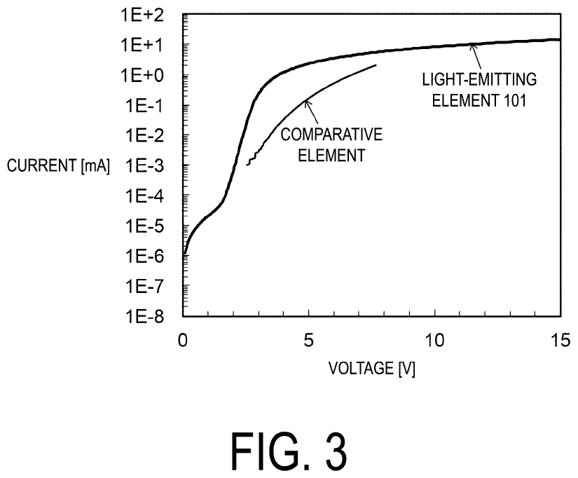

FIG. 3 is a graph illustrating the voltage-current characteristics of the light-emitting element 101 and a comparative element, respectively. The comparative element is, as compared with the light-emitting element 101, provided with junction between the light-emitting layer 3 and the charge function layer 5 and does not include the buffer layer 4.

By determining circuit parameters from the equivalent circuit of the light-emitting element 101 illustrated in FIG. 2, accurate fitting can be performed. Here, “accurate fitting” means matching including a shape of a curve indicating electrical characteristics and a differential (in other words, a rate of change) by a voltage thereof. Since the rate of change reflects a physical process of charge transport of the light-emitting element 101, the light-emitting element 101 includes only one QLED 10 as the light-emitting diode.

It is found that a rising voltage of a current in the comparative element is around 3 V, while the rising voltage of the current in the light-emitting element 101 is 2 V, which is lower than that in the comparative element by around 1 V, and that a slope of the rising voltage of the current in the light-emitting element 101 is changed to a steeper direction.

In general, as the radiative recombination of the injected charges more efficiently occurs, a current flowing through the QLED exhibits a steep slope with respect to the voltage. Therefore, it can be presumed that, in the light-emitting element 101, the charges are efficiently injected into each of the plurality of first quantum dots 8, and radiative recombination efficiency of the charges injected into each of the plurality of first quantum dots 8 is also improved, as compared with the comparative element.

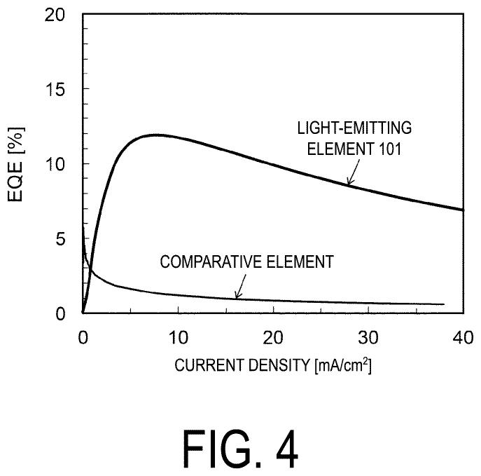

FIG. 4 is a graph illustrating current density-EQE (external quantum efficiency) characteristics of each of the light-emitting element 101 and the comparative element.

As illustrated in FIG. 4, a maximum value of the EQE with respect to the current density in the light-emitting element 101 is around 12%, which is significantly improved from the maximum value of the EQE with respect to the current density of around 5% in the comparative element. This is consistent with an assumption based on the voltage-current characteristics illustrated in FIG. 3.

A peak of the EQE appears at a current density equal to or lower than 1 mA/cm² in the comparative element, while the peak of the EQE appears at a current density at or near 10 mA/cm² in the light-emitting element 101. This suggests that the charges can be injected into each of the plurality of first quantum dots 8 to a level corresponding to a radiative recombination rate of each of the plurality of first quantum dots 8.

The above results indicate that almost all the current flowing through the light-emitting element 101 flows through each of the plurality of first quantum dots 8 without waste and contributes to light emission.

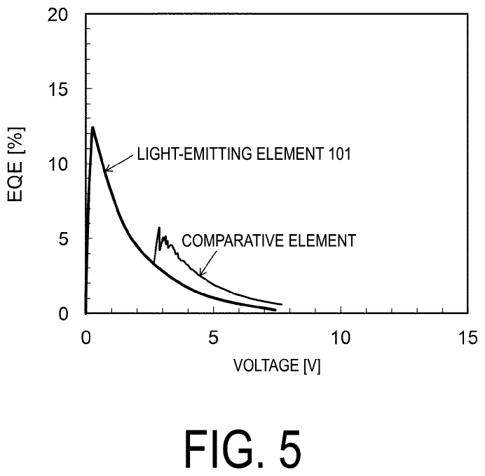

FIG. 5 is a graph illustrating voltage-EQE characteristics of each of the light-emitting element 101 and the comparative element.

As illustrated in FIG. 5, a voltage at which the peak of the EQE appears in the light-emitting element 101 is shifted to a low voltage side by around 2 V from the voltage at which the peak of the EQE appears in the comparative element, which indicates that injection loss of the charges can be significantly reduced.

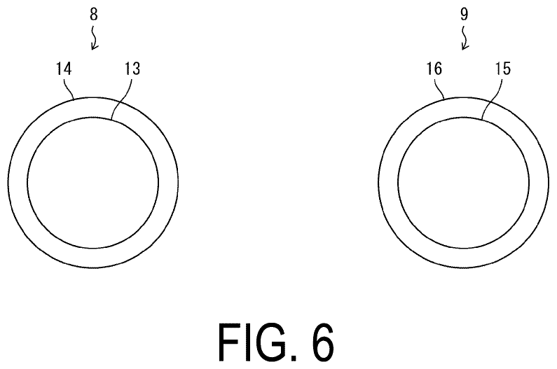

FIG. 6 is an enlarged view of an example of each of the first quantum dot 8 and the second quantum dot 9. Each of the plurality of first quantum dots 8 may include a core 13 and a shell 14. Each of the plurality of second quantum dots 9 may include a core 15 and a shell 16 made of a material identical to each other.

At least one of the plurality of first quantum dots 8 and the plurality of second quantum dots 9 may include a core containing a first compound and a shell containing a second compound, and the inorganic compound that is a constituent element of the continuous film 7 may be different from the first compound. Electron affinity of the inorganic compound may be smaller than electron affinity of the second compound. Ionization potential of the inorganic compound may be larger than ionization potential of the second compound. Each of the electron affinity and the ionization potential of the inorganic compound may be identical to the electron affinity and the ionization potential of the second compound. That is, the electron affinity of the inorganic compound may be identical to the electron affinity of the second compound, and the ionization potential of the inorganic compound may be identical to the ionization potential of the second compound.

The charge function layer 5 may include the electron transport layer containing at least one of ZnO, MgO, ZnMgO, and LiZnO.

The charge function layer 5 may include the hole transport layer containing at least one of PVK, TFB, and p-TPD. PVK, TFB, and p-TPD are abbreviations for the following materials, respectively.
PVK: Poly(9-vinylcarbazole)
TFB: Poly[(9,9-dioctylfluorenyl-2,7-diyl)-co-(4,4′-(N-(4-sec-butylphenyl)) diphenylamine)]
p-TPD: Poly[N,N′-bis(4-butylphenyl)-N,N′-bis(phenyl)-benzidine]

A ratio of the total weight of an organic matter contained in the buffer layer 4 to the total weight of the plurality of second quantum dots 9 may be equal to or less than 10%. A surface of each of the plurality of second quantum dots 9 may be configured with an inorganic semiconductor. The buffer layer 4 may be thinner than the light-emitting layer 3.

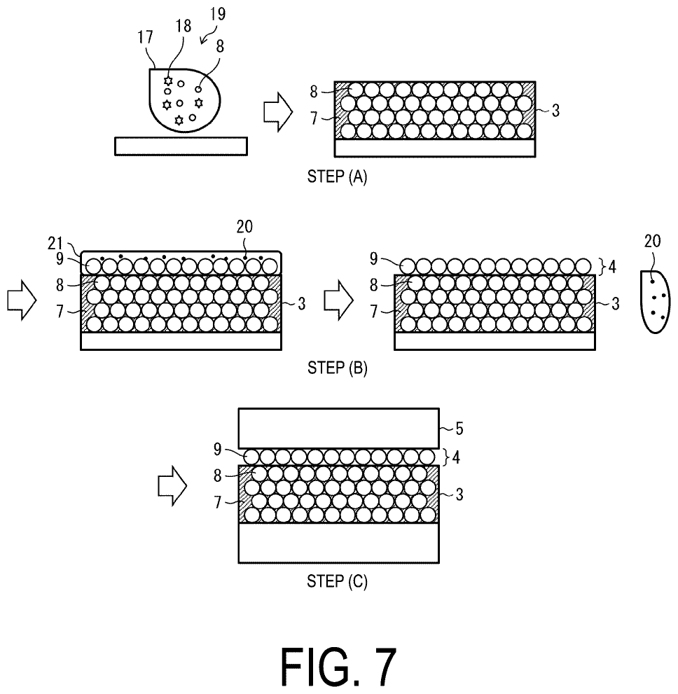

FIG. 7 is a diagram for describing a manufacturing method for the light-emitting element 101. The manufacturing method for the light-emitting element 101 includes steps (A) to (C).

(A) The light-emitting layer 3 including the continuous film 7 of the inorganic compound and the plurality of first quantum dots 8 included in the continuous film 7 is formed.

In step (A), for example, a precursor 18 of the metal sulfide and a large number of the first quantum dots 8 may be dispersed in a polar solvent 17 to prepare a quantum dot dispersion 19, and the quantum dot dispersion 19 may be applied, exposed, and developed to form the light-emitting layer 3. A material of the continuous film 7 may be, for example, ZnS. By step (A), an organic ligand coordinated to the large number of first quantum dots 8 or contained in the quantum dot dispersion 19 is reduced in the light-emitting layer 3 to such an extent that the organic ligand does not substantially affect element characteristics. Here, influence of the organic ligand on the element characteristics means that in the voltage-current characteristics, a current component proportional to a power exceeding 1 of the voltage is generated in a region where a current rises, and as a result, a current component different from any of (1) an ohmic current proportional to a voltage and (2) a diode current proportional to voltage power of e (the base of natural logarithm, approximately 2.71828) is generated. Since the current component resulting from the organic ligand flows outside the first quantum dot 8, it does not contribute to the EQE of the light-emitting element 101 at all.

(B) The buffer layer 4 is formed on the light-emitting layer 3 by forming, on the light-emitting layer 3, a buffer layer intermediate 21 containing an organic ligand 20 and the plurality of second quantum dots 9 and removing the organic ligand 20 from the buffer layer intermediate 21 formed.

(C) The charge function layer 5 in contact with the plurality of second quantum dots 9 is formed on the buffer layer 4.

In step (A), the light-emitting layer 3 is mineralized. Here, the mineralization of the light-emitting layer 3 may mean that the plurality of first quantum dots 8 are embedded in the continuous film 7 by using the continuous film 7 made of a semiconductor material identical to the shell 14 of each of the plurality of first quantum dots 8 and reducing the organic ligand content to such an extent that the element characteristics are not substantially affected. By mineralizing the light-emitting layer 3, it is possible to prevent deterioration of each of the plurality of first quantum dots 8 and to improve reliability.

In step (B), the plurality of second quantum dots 9 are layered on the mineralized light-emitting layer 3. A method for layering the plurality of second quantum dots 9 may be a general coating method or printing method.

Subsequently, ethanol is dropped onto the plurality of second quantum dots 9 to remove the organic ligand 20 from the plurality of second quantum dots 9. This step may be repeated multiple times as needed. A ratio of the total weight of the organic ligand 20 remaining in the buffer layer 4 to the total weight of the plurality of second quantum dots 9 may be equal to or less than 10%. A weight ratio can be evaluated using, for example, gas chromatography-mass spectrometry (GCMS) and Fourier transform infrared spectroscopy (FTIR). Examples of a material for removing the organic ligand 20 from the plurality of second quantum dots 9 include methanol and isopropyl alcohol (IPA) in addition to ethanol.

Next, the charge function layer 5 and the electrode 6 are layered in this order on the plurality of second quantum dots 9 (in other words, the buffer layer 4) by a general method. Finally, an entire light-emitting element 101 is sealed to complete a display panel or a test element group (TEG).

A maximum number of the second quantum dots 9 along a thickness direction of the buffer layer 4 may be one. That is, the buffer layer 4 may be a single layer of the second quantum dot 9 over the entire thereof. This facilitates removal of the organic ligand 20 in step (B).

In the light-emitting element 101, the charge function layer 5 and the plurality of second quantum dots 9 are in contact with each other, and a surface of each of the plurality of second quantum dots 9 and the charge function layer 5 are hardly in contact with the organic ligand 20 which may slightly remain around the plurality of second quantum dots 9 or the mineralized light-emitting layer 3. Thus, the junction between the light-emitting layer 3 and the charge function layer 5 is practically limited to one type of the special semiconductor junction described above.

A separation distance between two of the plurality of second quantum dots 9 may be equal to or less than 50 nm or equal to or less than 20 nm. This corresponds to approximately half or less of a particle diameter of the second quantum dot 9.

The second quantum dot 9 may be a nanoparticle of a material identical to the shell 14 (refer to FIG. 6) of the first quantum dot 8.

The first quantum dot 8 of the light-emitting layer 3 and the second quantum dot 9 of the buffer layer 4 may be in contact with each other, but are not limited thereto and may be separated from each other. However, it is needless to say that a current needs to flow between each of the plurality of first quantum dots 8, each of the plurality of second quantum dots 9, and the charge function layer 5.

The buffer layer 4 may be provided between the light-emitting layer 3 and the charge function layer 2. The function of the buffer layer 4 between the light-emitting layer 3 and the charge function layer 2 is identical to the function of the buffer layer 4 between the light-emitting layer 3 and the charge function layer 5.

Referring to FIG. 6, when the shell 14 of the first quantum dot 8 and the core 15 in the case where the second quantum dot 9 includes only the core 15 (not include the shell 16) are made of a material identical to each other, unintended light emission caused by the second quantum dot 9 can be suppressed.

### Second Embodiment

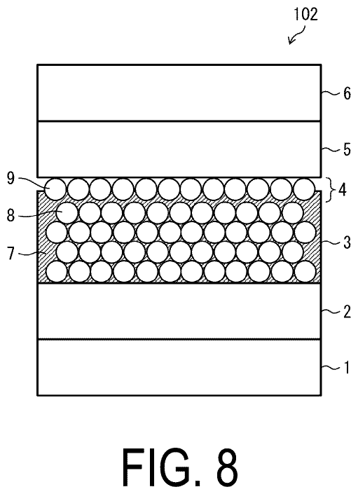

FIG. 8 is a cross-sectional view illustrating a schematic configuration of a light-emitting element 102 according to a second embodiment of the disclosure. The configuration of the light-emitting element 102 is different from the configuration of the light-emitting element 101 in that part of each of the plurality of second quantum dots 9 is embedded in the continuous film 7, and the other configurations are identical to those of the light-emitting element 101. Also, in the light-emitting element 102, there is no change in that both the continuous film 7 and the plurality of first quantum dots 8 are not in contact with the charge function layer 5.

A manufacturing method for the light-emitting element 102 is different from the manufacturing method for the light-emitting element 101 in the following points, and is otherwise identical to the manufacturing method for the light-emitting element 101. After the buffer layer 4 is formed, an amount of a solution (refer to FIG. 7) prepared by dispersing the precursor 18 of the metal sulfide and a large number of the second quantum dots 9 in the polar solvent 17 is adjusted to mineralize approximately one half of the buffer layer 4 on a light-emitting layer 3 side. This is a method similar to the mineralization of the light-emitting layer 3.

### Third Embodiment

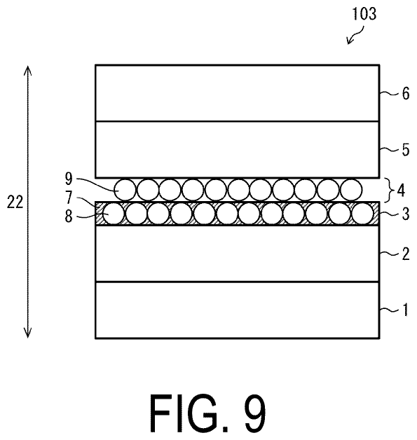

FIG. 9 is a cross-sectional view illustrating a schematic configuration of a light-emitting element 103 according to a third embodiment of the disclosure. The configuration of the light-emitting element 103 is different from the configuration of the light-emitting element 101 in the following points and is identical to the configuration of the light-emitting element 101 in the other points. A maximum number of the first quantum dots 8 along a thickness direction 22 of the light-emitting element 103 is one, and a maximum number of the second quantum dots 9 along the thickness direction 22 of the light-emitting element 103 is one.

In the light-emitting element 103, a size of the first quantum dot 8 and/or the second quantum dot 9 may be reduced as much as possible to cope with a shift to a longer wavelength.

The light-emitting layer 3 and the buffer layer 4 of the light-emitting element 103 are the thinnest layers in the light-emitting layer 3 and the buffer layer 4 of the light-emitting element according to the disclosure. In the light-emitting element 103, the mineralized light-emitting layer 3 and the buffer layer 4 from which most of the organic ligand 20 (refer to FIG. 7) is removed are layered. In addition, a series resistance of the light-emitting element 103 is around an order of 100 ohms at maximum. Therefore, in the light-emitting element 103, almost all of the external electrical field is applied to the very thin light-emitting layer 3 and buffer layer 4. As a result, in the light-emitting element 103, an electrical field of the light-emitting layer 3 in which radiative recombination occurs can be extremely increased to several MV/cm or more, and electron-hole spatial separation due to the Stark effect, which may cause a decrease in the EQE, can be suppressed. Accordingly, it is possible to achieve the light-emitting element 103 having high luminous efficiency (EQE).

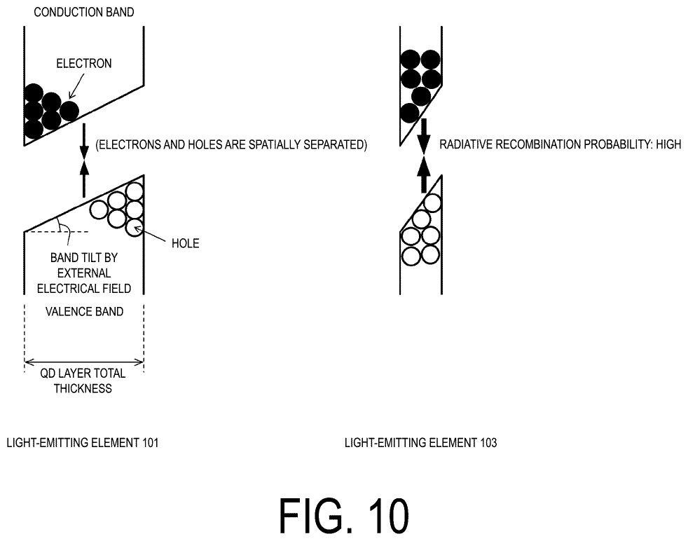

FIG. 10 is a diagram illustrating a band tilt of the first quantum dot 8 and distributions of electrons and holes when the external electrical field is applied to each of the light-emitting element 101 and the light-emitting element 103.

In the light-emitting element 101, electrons and holes are spatially separated in the thickness direction of the light-emitting layer 3 (“QD layer total thickness” in FIG. 10) due to the band tilt of the first quantum dot 8 caused by the external electrical field, and thus there is a limit to a level of radiative recombination probability.

On the other hand, the light-emitting element 103 has the thinnest thickness achievable of the light-emitting layer 3, and a very strong electrical field can be applied to the light-emitting layer 3. In the light-emitting element 103, due to the thin light-emitting layer 3 and the strong electrical field, the band tilt of the first quantum dot 8 increases in a narrow width. As a result, the spatial separation between electrons and holes is suppressed, and the high EQE can be achieved.

### Fourth Embodiment

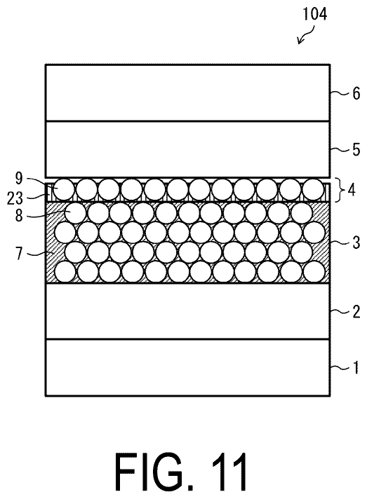

FIG. 11 is a cross-sectional view illustrating a schematic configuration of a light-emitting element 104 according to a fourth embodiment of the disclosure. The configuration of the light-emitting element 104 is different from the configuration of the light-emitting element 101 in that the buffer layer 4 includes an insulating film 23 in which part of each of the plurality of second quantum dots 9 is embedded, and the other configurations are identical to those of the light-emitting element 101. Also, in the light-emitting element 104, there is no change in that both the continuous film 7 and the plurality of first quantum dots 8 are not in contact with the charge function layer 5.

Examples of the insulating film 23 include a film containing at least one of an oxide of aluminum, an oxide of gallium, an oxide of indium, an oxide of titanium, an oxide of scandium, an oxide of yttrium, an oxide of zirconium, an oxide of silicon, and an oxide of carbon. Another example of the insulating film 23 includes a compound containing fluorine.

The insulating film 23 is, after the buffer layer 4 is formed, obtained by applying an insulating solution on the buffer layer 4 and solidifying the insulating solution. Examples of an insulating material that is coatable in a liquid state include amorphous TFE (tetrafluoroethylene), a spin-on-glass (SOG) material, and dimethyl silicone. These insulating materials can be, after application, solidified by heat treatment. Amorphous TFE and dimethyl silicone contain an organic matter and/or an organic structure in a molecular structure, but have high insulation properties as a compound, and the organic matter and/or organic structure does not become a medium of an unnecessary current.

In the light-emitting element 104, the insulating film 23 and the charge function layer 5 are not in contact with each other. However, the insulating film 23 may be in contact with the charge function layer 5, or may be filled between the light-emitting layer 3 and the charge function layer 5 without a gap. An upper surface of the insulating film 23 may be flush with an upper surface of at least one of the plurality of second quantum dots 9. The second quantum dot 9 and the charge function layer 5 may be separated from each other as long as a current flows by the tunnel effect. However, in order to ensure that a current flows between the second quantum dot 9 and the charge function layer 5, a height of the insulating film 23 is preferably adjusted so that the second quantum dot 9 and the charge function layer 5 are reliably brought into contact with each other.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

For example, the buffer layer 4 of the second embodiment is not formed after the light-emitting layer 3 is formed, but may be formed by adjusting an amount of the solution at the time of forming the light-emitting layer 3 to expose at least a part of the first quantum dot 8 in contact with the charge function layer 5 like the second quantum dot 9 in FIG. 8, so that a region including the first quantum dot 8 in contact with the charge function layer 5 is used as the buffer layer 4. In this case, the first quantum dot 8 in contact with the charge function layer 5 becomes the second quantum dot 9, and the first quantum dot 8 and the second quantum dot 9 have configurations identical to each other.

1. A light-emitting element, comprising:
a charge function layer;
a light-emitting layer including a continuous film of an inorganic compound and a plurality of first quantum dots included in the continuous film; and
a buffer layer including a plurality of second quantum dots in contact with the charge function layer and the continuous film.

2. The light-emitting element according to claim 1,
wherein each of the plurality of first quantum dots includes a core and a shell.

3. The light-emitting element according to claim 1,
wherein each of the plurality of second quantum dots includes a core and a shell made of a material identical to each other.

4. The light-emitting element according to claim 1,
wherein at least one of the plurality of first quantum dots and the plurality of second quantum dots includes a core containing a first compound and a shell containing a second compound, and
the inorganic compound is different from the first compound.

5. The light-emitting element according to claim 4,
wherein electron affinity of the inorganic compound is smaller than electron affinity of the second compound.

6. The light-emitting element according to claim 4,
wherein ionization potential of the inorganic compound is larger than ionization potential of the second compound.

7. The light-emitting element according to claim 4,
wherein each of the electron affinity and the ionization potential of the inorganic compound is identical to the electron affinity and the ionization potential of the second compound.

8. The light-emitting element according to claim 1,
wherein the charge function layer includes an electron transport layer containing at least one of ZnO, MgO, ZnMgO, and LiZnO.

9. The light-emitting element according to claim 1,
wherein the charge function layer includes a hole transport layer containing at least one of PVK, TFB, and p-TPD.

10. The light-emitting element according to claim 1,
wherein a ratio of a total weight of an organic matter included in the buffer layer to a total weight of the plurality of second quantum dots is equal to or less than 10%.

11. The light-emitting element according to claim 1,
wherein part of each of the plurality of second quantum dots is embedded in the continuous film.

12. The light-emitting element according to claim 1,
wherein the buffer layer includes an insulating film embedded with part of each of the plurality of second quantum dots.

13. The light-emitting element according to claim 1,
wherein a maximum number of the first quantum dots along a thickness direction of the light-emitting element is one, and a maximum number of the second quantum dots along the thickness direction of the light-emitting element is one.

14. The light-emitting element according to claim 1,
wherein a surface of each of the plurality of second quantum dots is configured with an inorganic semiconductor.

15. The light-emitting element according to claim 1,
wherein the buffer layer is thinner than the light-emitting layer.

16. A manufacturing method for a light-emitting element, comprising:
forming a light-emitting layer including a continuous film of an inorganic compound and a plurality of first quantum dots included in the continuous film;
forming, on the light-emitting layer, a buffer layer intermediate containing an organic ligand and a plurality of second quantum dots;
forming a buffer layer by removing the organic ligand from the buffer layer intermediate formed on the light-emitting layer; and
forming, on the buffer layer, a charge function layer in contact with the plurality of second quantum dots.
